(19) United States
(12) Patent Application Publication
(10) Pub. No.: US 2014/0321033 A1
(43) Pub. Date: Oct. 30, 2014

(54) ENHANCED MOBILE ELECTRONIC DEVICE AND BATTERY PACK

(71) Applicant: MOTOROLA MOBILITY LLC, Chicago, IL (US)

(72) Inventors: Jerald A. Hallmark, Sugar Hill, GA (US); Steven R. Fischl, Lawrenceville, GA (US); Jason N. Howard, Alpharetta, GA (US); David Kyungtag Lim, Green Oaks, IL (US); Hossein Maleki, Duluth, GA (US); Michael F. Spence, Libertyville, IL (US); Timothy J. Sutherland, Gurnee, IL (US); Jason P. Wojack, Libertyville, IL (US)

(73) Assignee: MOTOROLA MOBILITY LLC, Chicago, IL (US)

(21) Appl. No.: 14/231,863

(22) Filed: Apr. 1, 2014

Related U.S. Application Data
(60) Provisional application No. 61/816,239, filed on Apr. 26, 2013.

(51) Int. Cl. H05K 7/02; H01M 2/02

(52) U.S. Cl. CPC H05K 7/02; H01M 2/0217
USPC 361/679.01; 429/163; 429/121

(57) ABSTRACT

A mobile electronic device with an enhanced battery pack construction is shown. The mobile electronic device (10) includes: a housing (12) including a front housing (14) and a rear housing (16) having a reservoir area (18); a user interface (20) connected to the front housing (14); and a battery pack (22) including a planar inwardly facing surface (24) and a nonplanar outwardly facing surface (26), the nonplanar outwardly facing surface (26) being substantially complementarily configured to be received in the reservoir area (18) of the rear housing (16). Advantageously, this construction helps to provide a uniquely shaped mobile electronic device with enhanced ergonomics, adapted to be comfortably held in a user's hand and can conform to a user's palm. Advantageously, this construction is adapted to accommodating expansion and contraction of the battery pack (22), when it comprises a Lithium Ion Polymer, in one embodiment.

### BACKGROUND OF THE INVENTION

1. Field of the Disclosure

The disclosure relates in general to improved mobile electronic devices and battery packs.

2. Background Art

There is a need for enhanced mobile electronic devices with improved features, such as large user interfaces, longer battery life, narrow profiles and unique form factors.

A mobile electronic device with the above features would be considered an improvement in the art.

Further, a mobile electronic device that is structurally robust and can withstand tough user environments, would be considered an improvement in the art.

It is therefore desirable to provide an improved mobile electronic device and battery pack that include desirable features and address user's needs.

### BRIEF DESCRIPTION OF THE DRAWINGS

FIG. 1 is an exemplary rear perspective view of a mobile electronic device, in one embodiment.

FIG. 2 is an exemplary cut away view along lines 2-2 of FIG. 1 of an embodiment of the mobile electronic device in FIG. 1, showing various components and a three tier battery pack of the mobile electronic device, in one embodiment.

FIG. 3 is an exemplary cut away view along lines 2-2 of FIG. 1 of an alternate two tier battery pack in the mobile electronic device in FIG. 1, in one embodiment.

FIG. 4 is an exemplary perspective view of a two tier battery pack configured to be fit in and conform to a portion of the mobile electronic device in FIG. 1, in one embodiment.

FIG. 5 is an exemplary perspective view of a three tier battery pack configured to be fit in and conform to a portion of the mobile electronic device in FIG. 1, in one embodiment.

FIG. 6 is an exemplary partial view of the battery pack and mobile electronic device in FIG. 2, with an edge portion of the battery pack shown bent, in one embodiment.

FIG. 7 is an exemplary top view of a printed circuit board construction with cut outs 92, configured to allow an edge portion of a battery pack to bend inwardly, as shown in FIGS. 2 and 6, in one embodiment.

### DETAILED DESCRIPTION OF THE INVENTION

The following is a detailed description and explanation of the preferred embodiments of the invention and best modes for practicing the invention.

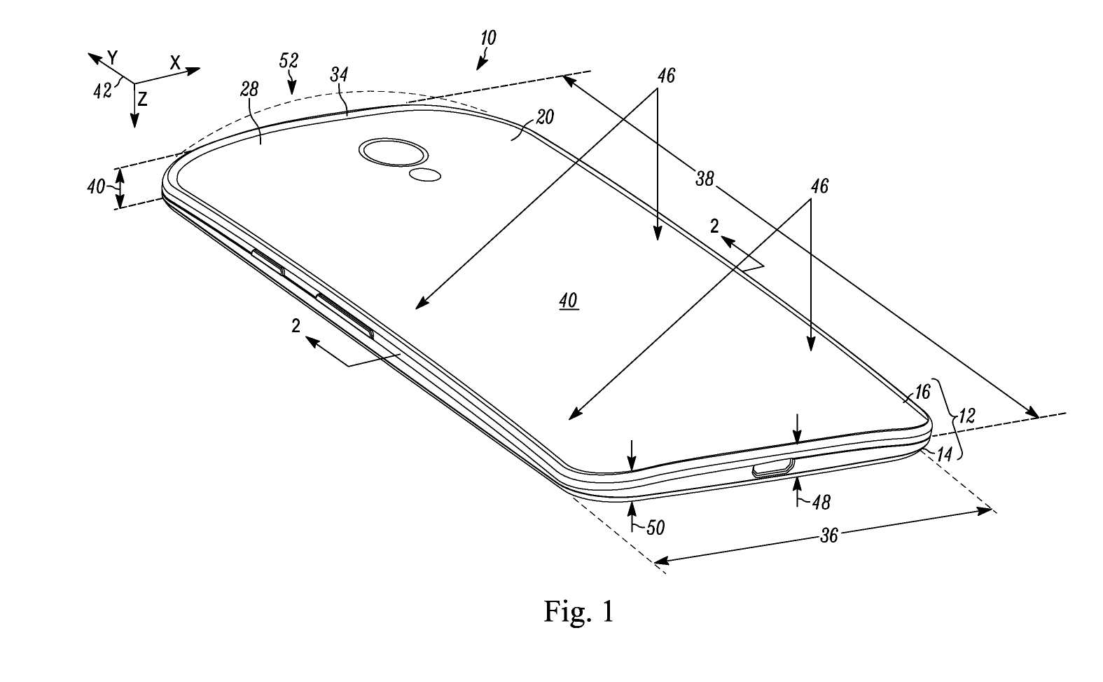

Referring to FIGS. 1-3, a mobile electronic device with an enhanced battery pack construction is shown. The mobile electronic device 10 includes: a housing 12 including a front housing 14 and a rear housing 16 having a reservoir area 18; a user interface 20 connected to the front housing 14; and a battery pack 22 including a planar inwardly facing surface 24 and a nonplanar outwardly facing surface 26, the nonplanar outwardly facing surface 26 being substantially complementarily configured to be received in the reservoir area 18 of the rear housing 16.

Advantageously, this construction helps to provide a uniquely shaped mobile electronic device with enhanced ergonomics, adapted to be comfortably held in a user's hand and can conform to a user's palm, in one embodiment.

Advantageously, this construction is adapted to accommodating expansion and contraction of the battery pack (22), when it comprises a Lithium Ion Polymer, in one embodiment. Advantageously, this construction helps to provide a robust, durable and narrow profile mobile electronic device desired by users.

The geometry and dimensions of electronic device 10 can vary. In one embodiment, the housing 12 includes a narrower z-dimension around the periphery than the z-dimension in the middle, for an enhanced touch and feel. User's like electronic devices with thin edges, as they can be easier to hold and pick up. Further, the housing 12 provides a design with enhanced ergonomics, that can be held comfortably in a user's hand and can conform to a user's palm.

The housing 12 comprises a resilient material sufficient to withstand the harsh environment that it will be exposed to.

The electronic device 10 componentry placement can vary. In one embodiment, the electronic device 10 can enclose the battery pack 22 slightly off center from a y-axis, to provide space for an antenna farm and other components, around a periphery of the housing, as desired.

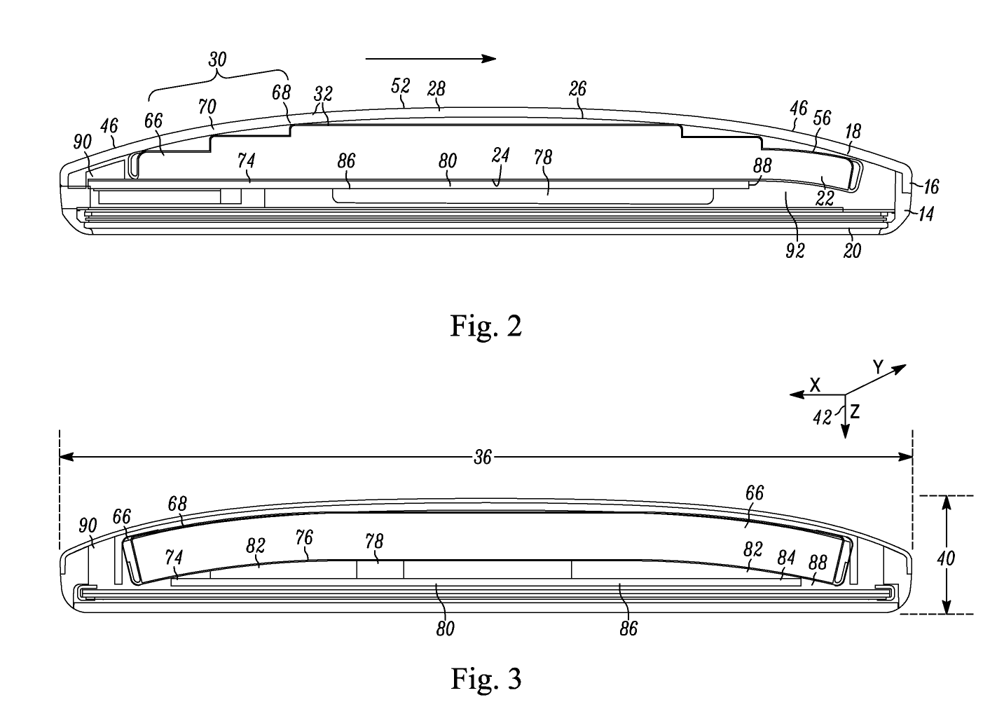

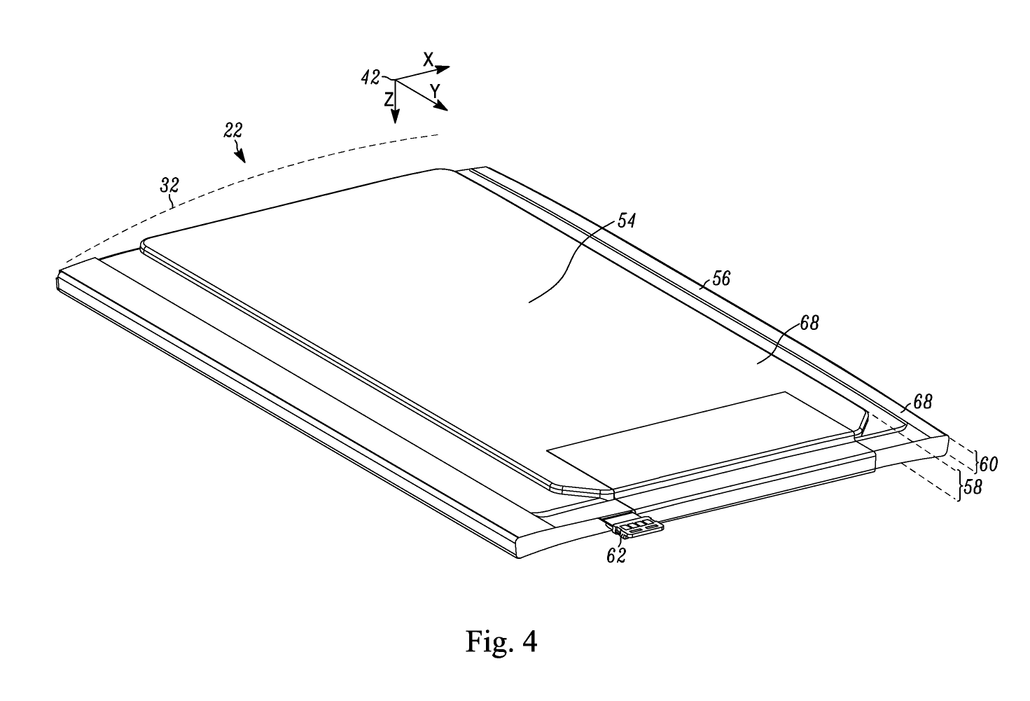

In FIGS. 2 and 3, the rear housing 16 includes a nonplanar rear surface 28 positioned adjacent to the nonplanar outwardly facing surface 26 of the battery pack 22, for enhanced structural integrity and desired dimensioning. Further, the nonplanar rear surface 28 provides a design with enhanced ergonomics, that can be held comfortably in a user's hand and can conform to a user's palm.

In one embodiment, the nonplanar outwardly facing surface 26 of the battery pack 22 includes a tiered construction 30, forming a generally curved or convex geometry 32, beneficially, adapted for conforming to the nonplanar rear surface 28 with enhanced ergonomics, as previously detailed.

In FIG. 1, the rear housing 16 is shown generally rectangular in shape 34 and can include an x-dimension defining a width 36, a y-dimension defining a length 38 and a z-dimension defining a depth or profile 40, as shown by compass 42. The rear housing 16 can include a central portion 44 and an edge portion 46, and a central profile 48 of the central portion 44 is wider in a z-dimension than an edge profile 50 of the edge portion 46. Likewise, the battery pack 22 in FIGS. 2 and 3, for example, can include a middle section 54 and an edge section 56, and a middle profile 58 of the middle section 54 is wider in a z-dimension than an edge profile 60 of the edge section 56. Beneficially, this construction can provide a desired industrial design and a convex design 52, complementarliy configured to receive the nonplanar surface 26 of the battery pack 22, defining an enclosure over the reservoir area 18, contributing to an enhanced battery compartment and interconnection.

The user interface 20 can include a touch screen display connected to and partially enclosed in the front housing 14, for providing an easily accessible touch screen to operate an electronic device.

The battery pack 22 includes a connector 62 extending outwardly, such as, in an x or y direction, for simplified connection to electrical components on a print circuit board and user interface, for example.

The battery pack 22 herein can vary. In a preferred embodiment, the battery pack 22 includes a Lithium Ion Polymer. One of the challenges to providing a narrow profile housing, is that the Lithium Ion Polymer cell(s) can expand and contract over time, based on amount of charge remaining, temperature, etc. These changes in volume need to be considered in any housing design, thus space, structure and tolerances, around the battery pack 22 need to be considered.

In one embodiment, the nonplanar outwardly facing surface 26 of the battery pack 22 includes a tiered construction 64 including a low tier 66 and a high tier 68, as shown in FIGS. 3 and 4. The tiered construction 64 can include the low tier 66 having larger dimensions in an x-dimension and a y-dimension than the high tier 68. The tiered construction can be generally rectangular in shape 72. Advantageously, in one embodiment, this construction allows more of the volume of the battery pack 22, in a middle area than near the edge, to better conform to a desired housing shape, when the battery pack 22 comprises a Lithium Ion Polymer, for example.

In another embodiment, the tiered construction 64 can be a multi-tiered construction including a low tier 66, a mid tier 70 and a high tier 68. The low tier 66 can have larger dimensions in an x-dimension and a y-dimension than the mid tier 70 and the mid tier 70 can have larger dimensions in the x-dimension and the y-dimension than the high tier 68.

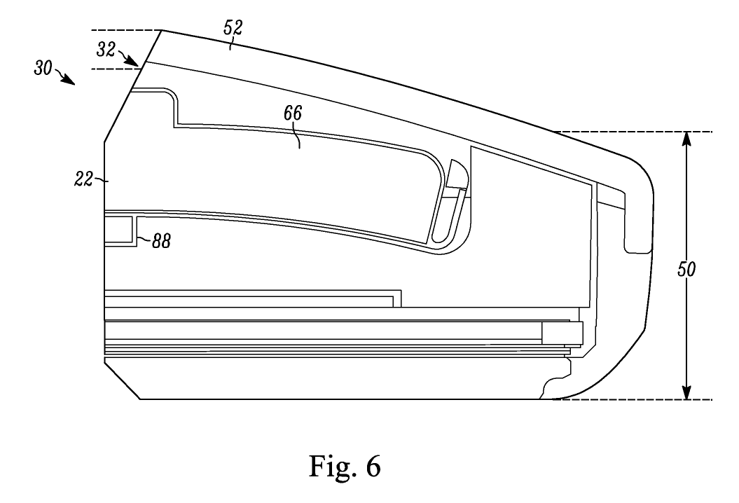

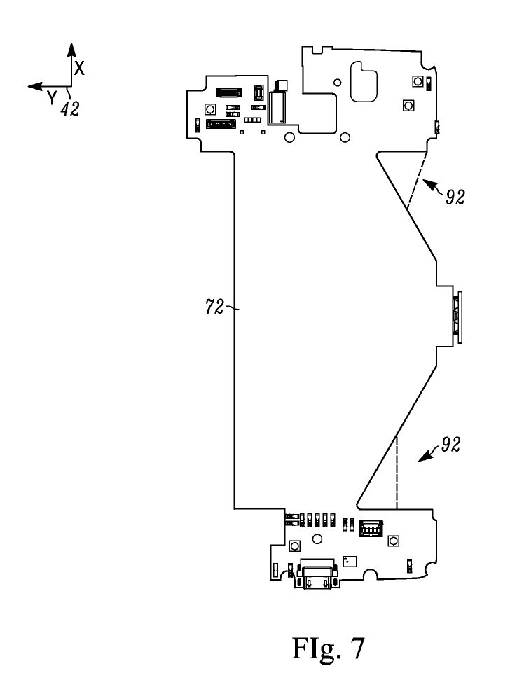

As shown in FIG. 3, the planar inwardly facing surface 24 of the battery pack 22 is placed adjacent to a printed circuit board 74. The printed circuit board 74 can include a battery facing side 76 populated with larger components 78 in a middle area 80 and smaller components 82 near an outer area 84 or a user interface facing side 86 populated with components 88. As should be understood, the printed circuit boards detailed herein can be populated with integrated circuits, chips and the like. As shown in FIG. 3, the battery pack 22 extends past an outer periphery 88 of the printer circuit board 74, to allow bending of the low tier 66 of the battery pack 22, for a narrow z-dimension. Referring to FIG. 7, an exemplary top view of the printed circuit 74 is shown. It can have cut outs 92, which are configured to allow an edge section 56 of the battery pack 22, to bend inwardly or downwardly, as shown in FIGS. 2, 5 and 6, in one embodiment.

As shown in FIGS. 2 and 3, the housing includes an antenna kick out structure 90 adjacent to an outer periphery 88 of the printed circuit board 74. In FIG. 2, the printed circuit board 74 is shifted slightly off center, or to the right in FIG. 2, and a bended edge section portion 56, so that other components can be placed near the housing 12 edge portion 46, on the left side. This structure allows placement of desired antennas in an antenna farm or other components in proximity to an outer periphery of the housing 12, for example.

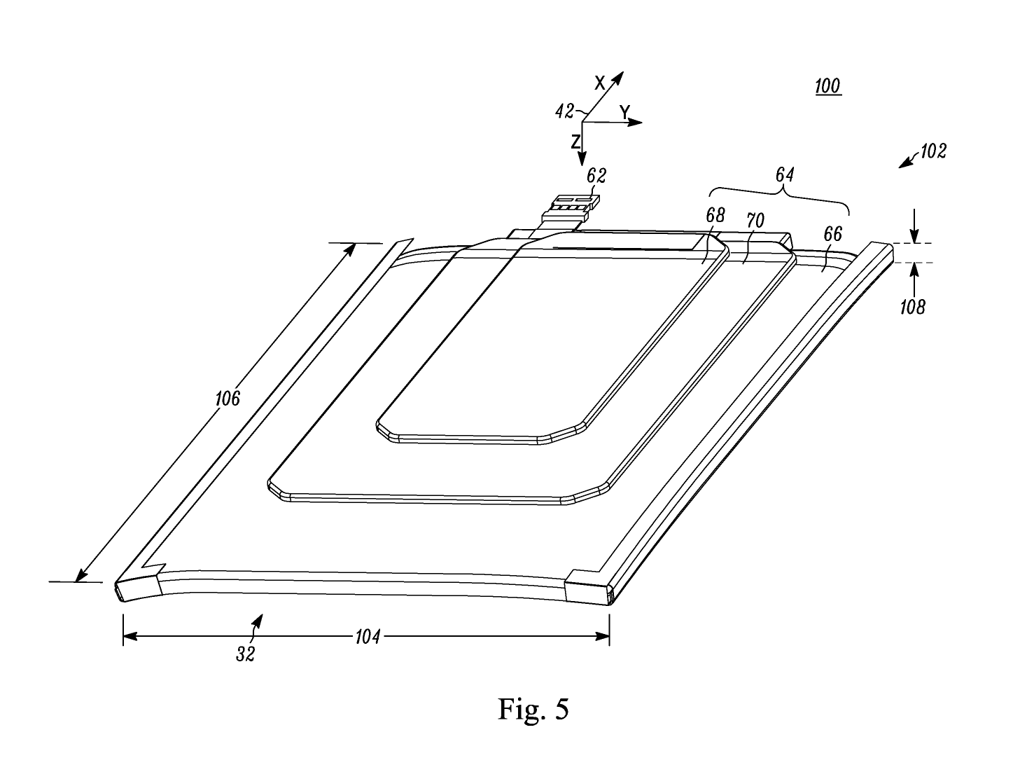

In another embodiment, as shown in FIG. 5, an enhanced battery pack 100 is disclosed. The battery pack 100 can be generally rectangular in shape 102 including an x-dimension defining a width 104, a y-dimension defining a length 106 and a z-dimension defining a depth 108; the battery pack 100 can include a planar inwardly facing surface 24 and a nonplanar outwardly facing surface 26, the nonplanar outwardly facing surface 26 can include a tiered construction 64; the battery pack 100 can further include a middle section 54 and an edge section 56, and a middle profile 58 of the middle section 54 is wider in a z-dimension than an edge profile 60 of the edge section 56. Advantageously, this construction helps to provide a desirably shaped battery pack configured to be easily placed in a narrow profile mobile electronic device desired by users.

The tiered construction 30 can define a substantially convex construction or geometry 32, shown in FIG. 5, for example, that can easily conform to the convex design 32, as shown in dashed line in FIG. 1. This provides a tailored battery compartment structure with a desired form factor.

In FIG. 4, the tiered construction 64 can include a low tier 66 and a high tier 68, the low tier 66 having larger dimensions in the x-dimension and the y-dimension than the high tier 68. Alternatively, the tiered construction 64 can include a low tier 66, a mid tier 70 and a high tier 68, the low tier 66 having larger dimensions in an x-dimension and a y-dimension than the mid tier 70 and the mid tier 70 having larger dimensions in the x-dimension and the y-dimension than the high tier 68, as shown in FIG. 5, for example.

The battery pack 100 can include a connector 62 extending outwardly, such as shown in FIG. 4 or 5, for a simplified connection to electronic components, for example.

Advantageously, as best shown in FIGS. 4 and 5, the convex geometry 32 of the battery pack 22, are similar, and this tolerance accommodates the battery pack's 22 potential expansion and contraction, when the battery pack 22 comprises a Lithium Ion Polymer.

Among the many advantages of the mobile electronic device are: superior capabilities, enhanced durability and performance, enhanced z dimension, reliability, comfortable, light weight, portable, user friendly, easy to use, economical, and attractive.

Although embodiments of the invention have been shown and described, it is to be understood that various modifications, substitutions, and rearrangements of parts, components, and/or process steps, as well as other uses of the mobile electronic device can be made by those skilled in the art without departing from the novel spirit and scope of this invention.

What is claimed is:

1: A mobile electronic device with an enhanced battery construction, comprising:
a housing including a front housing and a rear housing having a reservoir;
a user interface connected to the front housing; and
a battery pack including a planar inwardly facing surface and a nonplanar outwardly facing surface, the nonplanar outwardly facing surface being substantially complementarily configured to be received in the reservoir of the rear housing.

2: A mobile electronic device in accordance with claim 1 wherein the rear housing includes a nonplanar rear surface adjacent to the nonplanar outwardly facing surface.

3: A mobile electronic device in accordance with claim 1 wherein the nonplanar outwardly facing surface of the battery pack includes a tiered construction.

4: A mobile electronic device in accordance with claim 1 wherein the nonplanar rear surface of the rear housing in substantially convex.

5: A mobile electronic device in accordance with claim 1 wherein the rear housing is generally rectangular and includes an x-dimension defining a width, a y-dimension defining a length and a z-dimension defining a depth.

6: A mobile electronic device in accordance with claim 1 wherein the housing includes a central portion and an edge portion, and a central profile of the central portion is wider in a z-dimension than an edge profile of the edge portion.

7: A mobile electronic device in accordance with claim 1 wherein the battery pack includes a middle section and an edge section, and a middle profile of the middle section is wider in a z-dimension than an edge profile of the edge section.

8: A mobile electronic device in accordance with claim 1 wherein the battery pack comprises a Lithium Ion Polymer.

9: A mobile electronic device in accordance with claim 1 wherein the nonplanar outwardly facing surface of the battery pack includes a tiered construction including a low tier and a high tier.

10: A mobile electronic device in accordance with claim 1 wherein the nonplanar outwardly facing surface of the battery pack includes a tiered construction including a low tier and a high tier, the low tier having larger dimensions in an x-dimension and a y-dimension than the high tier.

11: A mobile electronic device in accordance with claim 1 wherein the nonplanar outwardly facing surface of the battery pack includes a tiered construction being generally rectangular in shape.

12: A mobile electronic device in accordance with claim 1 wherein the nonplanar outwardly facing surface of the battery pack includes a tiered construction including a low tier, a mid tier and a high tier.

13: A mobile electronic device in accordance with claim 1 wherein the nonplanar outwardly facing surface of the battery pack includes a tiered construction including a low tier, a mid tier and a high tier, the low tier having larger dimensions in an x-dimension and a y-dimension than the mid tier and the mid tier having larger dimensions in the x-dimension and the y-dimension than the high tier.

14: A mobile electronic device in accordance with claim 1 wherein the planar inwardly facing surface of the battery pack is placed adjacent to a printed circuit board.

15: A mobile electronic device in accordance with claim 14 wherein the printed circuit board includes a battery facing side populated with larger components in a middle area and smaller components near an outer area or a user interfacing side populated with components.

16: A mobile electronic device in accordance with claim 14 wherein the battery extends past an outer periphery of the printer circuit to allow bending and a narrow profile in a z-dimension.

17: A mobile electronic device in accordance with claim 14 wherein the housing includes an antenna kick out structure adjacent to an outer periphery of the printer circuit.

18: An enhanced battery construction, comprising:
a battery pack generally rectangularly dimensioned including an x-dimension defining a width, a y-dimension defining a length and a z-dimension defining a depth;
the battery pack including a planar inwardly facing surface and a nonplanar outwardly facing surface, the nonplanar outwardly facing surface including a tiered construction;
the battery pack further includes a middle section and an edge section, and a middle profile of the middle section is wider in the z-dimension than an edge profile of the edge section.

19: An enhanced battery construction in accordance with claim 18 wherein the tiered construction defines a substantially convex construction.

20: An enhanced battery construction in accordance with claim 18 wherein the tiered construction includes a low tier and a high tier, the low tier having larger dimensions in the x-dimension and the y-dimension than the high tier.

21: An enhanced battery construction in accordance with claim 18 wherein the tiered construction includes a low tier, a mid tier and a high tier, the low tier having larger dimensions in an x-dimension and a y-dimension than the mid tier and the mid tier having larger dimensions in the x-dimension and the y-dimension than the high tier.

22: An enhanced battery construction in accordance with claim 18 wherein the battery pack includes a connector extending outwardly in a y-direction.

23: An enhanced battery construction in accordance with claim 18 wherein the battery pack comprises a Lithium Ion Polymer.
